(19) United States
(12) Patent Application Publication
(10) Pub. No.: US 2012/0197559 A1
(43) Pub. Date: Aug. 2, 2012

(54) METHOD OF PREDICTING PROBABILITY OF ABNORMALITY OCCURRENCE IN OIL-FILLED ELECTRICAL DEVICE

(75) Inventors: Eiichi Nagao, Chiyoda-ku (JP); Tsuyoshi Amimoto, Chiyoda-ku (JP); Fukutaro Kato, Chiyoda-ku (JP); Noboru Hosokawa, Chiyoda-ku (JP); Kota Mizuno, Chiyoda-ku (JP)

(73) Assignee: Mitsubishi Electric Corporation, Chiyoda-ku (JP)

(21) Appl. No.: 13/501,141

(22) PCT Filed: Dec. 24, 2009
(86) PCT No.: PCT/JP2009/071441

§ 371 Date: Apr. 10, 2012

(51) Int. Cl. G01R 31/00; G06F 19/00

(52) U.S. Cl. 702/58

(57) ABSTRACT

The present invention is a method of predicting the probability of abnormality occurrence in an oil-filled electrical device, including the steps of: measuring a residual dibenzyl disulfide concentration in an insulating oil sampled from an oil-filled electrical device in operation; determining an estimated decrease of the residual dibenzyl disulfide concentration, relative to an initial dibenzyl disulfide concentration at the start of operation of the oil-filled electrical device; calculating the initial dibenzyl disulfide concentration from the residual dibenzyl disulfide concentration and the estimated decrease; and comparing the initial dibenzyl disulfide concentration with a specific management value.

### TECHNICAL FIELD

The present invention relates to a method of predicting the probability of abnormality occurrence in an oil-filled electrical device. In the case for example of an oil-filled electrical device such as transformer having a copper coil that is wrapped with electrically insulating paper and placed in an electrically insulating oil, the invention relates to a method of predicting the probability of occurrence of abnormality due to copper sulfide deposited on the insulating paper.

### BACKGROUND ART

An oil-filled electrical device such as oil-filled transformer is structured to have electrically insulating paper wrapped around coil's copper which is an electrically conducting medium, and thereby prevent copper coil turns adjacent to each other from being short-circuited.

A mineral oil used in the oil-filled transformer contains a sulfur component. It is known that the sulfur component reacts with copper parts in the oil and electrically conductive copper sulfide is deposited on the surface of insulating paper to form an electrically conducting path between turns adjacent to each other, resulting in a problem such as occurrence of dielectric breakdown (for example, NPL 1: CIGRE TF A2.31, “Copper sulphide in transformer insulation,” ELECTRA, No. 224, pp. 20-23, 2006).

The insulating oil used in the oil-filled electrical device, however, is of a large amount and generally used over a long period of time, and therefore, it is not easy to replace the insulating oil with an insulating oil containing no sulfur component. Thus, regarding an oil-filled electrical device using an insulating oil containing a sulfur component, there has been the need for a method that can predict the probability of occurrence of abnormality such as dielectric breakdown caused by deposition of copper sulfide.

As one of substances in the insulating oil that cause copper sulfide to be deposited, dibenzyl disulfide is known (for example, NPL 2: F. Scatiggio, V. Tumiatti, R. Maina, M. Tumiatti, M. Pompilli and R. Bartnikas, “Corrosive Sulfur in Insulating Oils: Its Detection and Correlated Power Apparatus Failures,” IEEE Trans. Power Del., Vol. 23, pp. 508-509, 2008). Thus, based on the concentration of dibenzyl disulfide in the insulating oil, the probability of abnormality occurrence in the oil-filled electrical device may be predicted.

However, it is known that dibenzyl disulfide reacts with copper to generate a complex in the oil, and the complex is adsorbed on the insulating paper and thereafter decomposed to deposit in the form of copper sulfide (for example, NPL 3: S. Toyama, J. Tanimura, N. Yamada, E. Nagao and T. Amimoto, “High sensitive detection method of dibenzyl disulfide and the elucidation of the mechanism of copper sulfide generation in insulating oil,” Doble Client Conf., Boston, Mass., USA, Paper IM-8A, 2008). As copper sulfide is generated, the concentration of dibenzyl disulfide in the mineral oil decreases. Therefore, even if the dibenzyl disulfide concentration in the mineral oil sampled from an existing device is merely measured, the probability of abnormality occurrence in the oil-filled electrical device cannot be predicted.

As a phenomenon that is different from the above-described deposition of copper sulfide on the surface of the insulating paper, deposition of copper sulfide on a metal surface has long been known. In this case, as the amount of generated copper sulfide increases, the copper sulfide could peel off from the metal surface and float in the insulating oil to degrade the insulation performance of the device.

As a method of preventing this phenomenon, there has been a method that provides in this device a member detecting generation of copper sulfide on the metal surface (for example, PTL 1: Japanese Patent Laying-Open No. 4-176108). This method can detect, from a decrease of the surface resistance of the detection member, generation of copper sulfide to thereby diagnose abnormality of the device.

The conventional diagnostic approach disclosed in the above-referenced PTL 1, however, concerns copper sulfide deposited on the metal surface which has long been known, and is directed to the phenomenon which is different from deposition of copper sulfide on the surface of insulating paper. Further, it uses an insulating plate made of epoxy resin, which is a different material from the coil's insulating paper of cellulose. Therefore, it is highly possible that deposition of copper sulfide on the coil's insulating paper cannot accurately be detected. Further, it must be manufactured by a complicated method of spraying copper powder on the insulating plate of epoxy resin and allowing it to be dispersed and adhered. Furthermore, in the case where the adhered copper peels off from the insulating plate of epoxy resin, it may become a metal foreign substance drifting in the insulating oil to deteriorate the insulation performance in the transformer. Moreover, there has also been a problem that device abnormality cannot be detected if copper sulfide precipitates at another site earlier than copper sulfide deposition on the detection member.

### CITATION LIST

### Patent Literature

PTL 1: Japanese Patent Laying-Open No. 4-176108

### Non Patent Literature

NPL 1: CIGRE TF A2.31, “Copper sulphide in transformer insulation,” ELECTRA, No, 224, pp. 20-23, 2006

NPL 2: F. Scatiggio, V. Tumiatti, R. Maina, M. Tumiatti, M. Pompilli and R. Bartnikas, “Corrosive Sulfur in Insulating Oils: Its Detection and Correlated Power Apparatus Failures,” IEEE Trans. Power Del., Vol. 23, pp. 508-509, 2008

NPL 3: S. Toyama, J. Tanimura, N. Yamada, E. Nagao and T. Amimoto, “High sensitive detection method of dibenzyl disulfide and the elucidation of the mechanism of copper sulfide generation in insulating oil,” Doble Client Conf., Boston, Mass., USA, Paper IM-8A, 2008

### SUMMARY OF INVENTION

### Technical Problem

The present invention has been made to solve the above-described problems, and an object of the present invention is to provide a method of predicting the probability that a malfunction will occur in the future due to generation of copper sulfide in an oil-filled electrical device, by analysis of the oil-filled electrical device in the current state.

### Solution To Problem

The present invention is a method of predicting probability of abnormality occurrence in an oil-filled electrical device, including the steps of:

(1) measuring a residual dibenzyl disulfide concentration in an insulating oil sampled from an oil-filled electrical device in operation;

(2) determining an estimated decrease of the residual dibenzyl disulfide concentration, relative to an initial dibenzyl disulfide concentration at the start of operation of the oil-filled electrical device;

(3) calculating the initial dibenzyl disulfide concentration from the residual dibenzyl disulfide concentration and the estimated decrease; and

(4) comparing the initial dibenzyl disulfide concentration with a specific management value.

Preferably, the estimated decrease is determined from an average rate of decrease of dibenzyl disulfide concentration and operating years of the oil-filled electrical device.

Preferably, the average rate of decrease is determined as a rate of decrease of dibenzyl disulfide concentration at an equivalent temperature of a coil provided in the oil-filled electrical device.

Preferably, the equivalent temperature of the coil is determined from test data of the oil-filled electrical device, an operating load factor, and information about an ambient temperature.

### Advantageous Effects of Invention

According to the method of predicting the probability of abnormality occurrence in an oil-filled electrical device of the present invention, the oil-filled electrical device in operation is analyzed to estimate the concentration of dibenzyl disulfide which is a causative substance contained in the mineral oil at the start of operation, to thereby enable prediction of the probability that a malfunction will occur in the future due to generation of copper sulfide in the oil-filled electrical device.

### BRIEF DESCRIPTION OF DRAWINGS

FIG. 1 is a flowchart showing steps (1) to (3) in a first embodiment.

FIG. 2 is a conceptual diagram for illustrating how to calculate the rate of decrease of the dibenzyl disulfide concentration in the first embodiment.

FIG. 3 is a conceptual diagram showing a temperature distribution obtained by a heat run test.

FIG. 4 is a conceptual diagram showing the coil temperature where the operating load factor is used as a parameter.

FIG. 5 is a conceptual diagram showing the coil temperature where the air temperature is used as a parameter.

FIG. 6 is a conceptual diagram for illustrating how to calculate the dibenzyl disulfide concentration at the start of operation in the first embodiment.

### DESCRIPTION OF EMBODIMENTS

### First Embodiment

In the following, a description will be given of an embodiment of the prediction method of the present invention in the case where the oil-filled electrical device is a transformer.

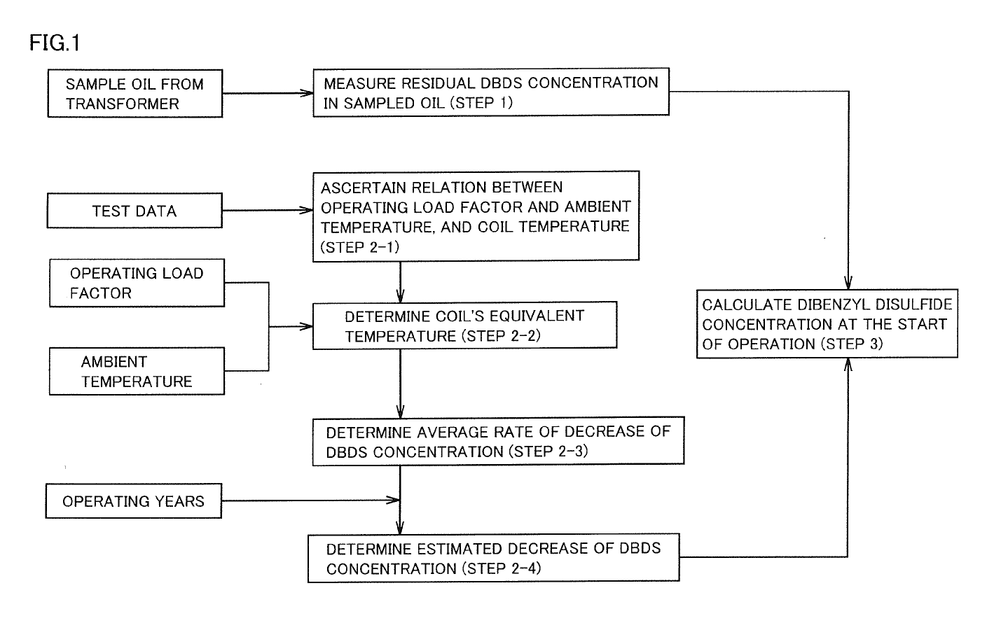

FIG. 1 is a flowchart for illustrating the following steps of the prediction method in the present embodiment:

(1) measuring a residual dibenzyl disulfide concentration in an insulating oil sampled from a transformer in operation;

(2) determining an estimated decrease of the residual dibenzyl disulfide concentration relative to an initial dibenzyl disulfide concentration at the start of operation of the transformer; and

(3) calculating the initial dibenzyl disulfide (hereinafter abbreviated as DBDS) concentration from the residual dibenzyl disulfide concentration and the estimated decrease. Details of each step will hereinafter be described.

STEP 1: Step of Measuring Residual DBDS Concentration

STEP 1 as shown in FIG. 1 includes the step of sampling oil from the transformer and the step of measuring the residual DBDS concentration in the sampled oil.

As a method of measuring the residual DBDS concentration in the sampled oil, any of various known methods may be used including for example a method by which analysis is conducted using a gas chromatograph (for example, NPL 3: S. Toyama, J. Tanimura, N. Yamada, E. Nagao and T. Amimoto, “High sensitive detection method of dibenzyl disulfide and the elucidation of the mechanism of copper sulfide generation in insulating oil,” Doble Client Conf., Boston, Mass., USA, Paper IM-8A, 2008). Such a method can be used to determine the residual DBDS concentration in the insulating oil.

STEP 2: Step of Determining Estimated Decrease of DBDS Concentration

As shown in FIG. 1, STEP 2 includes the steps of:

ascertaining, from test data of the transformer, a relation between the operating load factor of the transformer and the ambient temperature, and the coil temperature in the transformer (STEP 2-1);

determining an equivalent temperature of the coil in the transformer, from the operating load factor of the transformer and information about the ambient temperature, and the relation obtained in STEP 2-1 (STEP 2-2);

determining the rate of decrease (average rate of decrease) of the DBDS concentration at the equivalent temperature of the coil (STEP 2-3); and

determining an estimated decrease of the DBDS concentration relative to the DBDS concentration at the start of operation, from information about the operating years of the transformer and the above-described average rate of decrease (STEP 2-4).

STEP 2-1: Step of Ascertaining Relation between Operating Load Factor of Transformer and Ambient Temperature, and Coil Temperature in Transformer

By a heat run test as described below, the relation between the operating load factor of the transformer and the ambient temperature, and the coil temperature in the transformer is ascertained.

<Heat Run Test>

A heat run test for a transformer refers to a test for measuring a temperature increase under a predetermined load condition, in order to ascertain characteristics of cooling the winding and iron core, and can be carried out for example by an equivalent load method based on short circuit in accordance with JEC-2200 (page 41 of JEC-2200). In this test, respective oil temperatures of the bottom part and the upper part of the transformer are actually measured. The temperature of the coil winding is calculated from the actually measured resistance value of the coil winding (page 42 of JEC-2200).

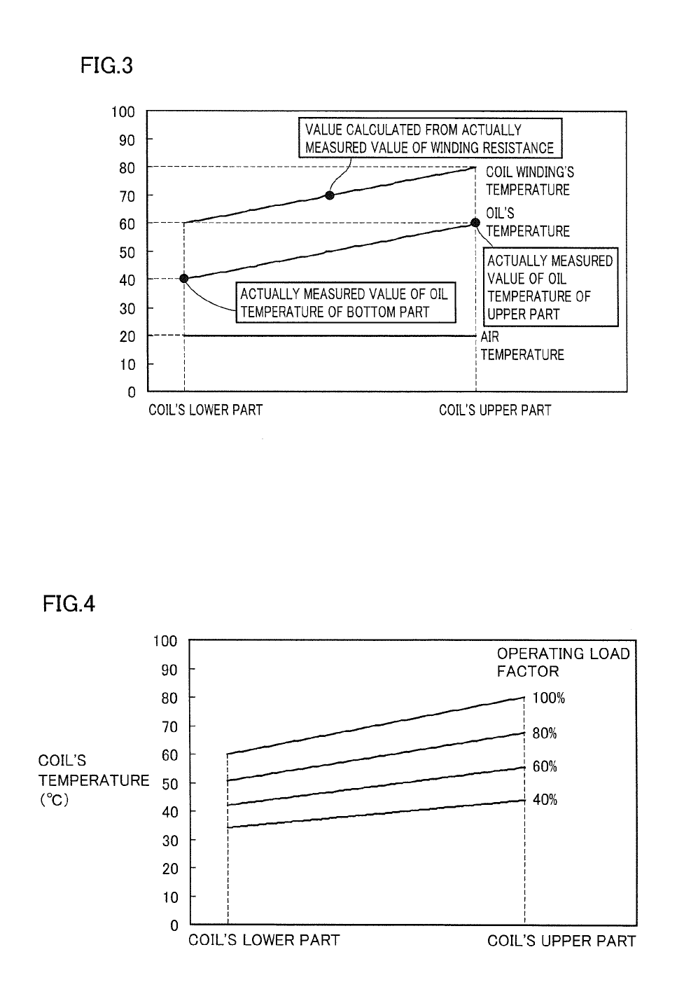

The temperature of the insulating oil and the temperature of the coil winding in the transformer determined by the heat run test are schematically shown in FIG. 3. Due to heat generation of the coil winding caused by electric current in the winding, the oil temperature is lowest at the lower part of the coil and is highest at the upper part thereof. As an example, a distribution as shown in FIG. 3 is obtained of the temperature of the insulating oil and the temperature of the coil winding in the transformer (the average temperature of the coil winding: 70° C., the oil temperature of the coil's upper part: 60° C., the oil temperature of the coil's lower part: 40° C.) (in FIG. 3, the numerical values of the vertical axis represent the temperatures of the insulating oil or coil winding, which are assumed values rather than actually measured values).

Based on this method, at a constant ambient temperature, the transformer was operated at a certain operating load factor (40%, 60%, 80%, 100%), and the temperature of the insulating oil of the bottom part of the transformer and that of the upper part of the transformer were measured. From the measured values, the coil temperature of each part (from the bottom part to the upper part) of the transformer in the case where the operating load factor is used as a parameter was determined. The results are schematically shown in FIG. 4.

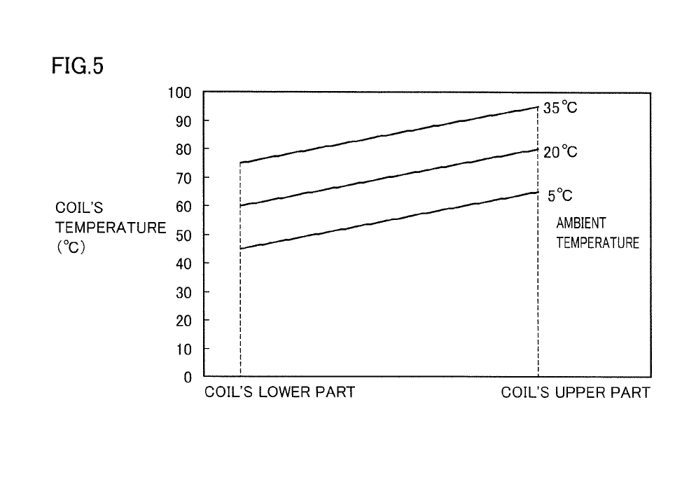

Further, at a certain ambient temperature (5° C., 20° C., 35° C.), the transformer was operated at a constant operating load factor, and the temperature of the insulating oil of the bottom part of the transformer and that of the upper part of the transformer were measured. From the measured values, the coil temperature of each part (from the bottom part to the upper part) of the transformer in the case where the ambient temperature was used as a parameter was measured. The results are schematically shown in FIG. 5.

In this way, the relation between the operating load factor of the transformer and the ambient temperature, and the coil temperature in the transformer can be ascertained.

STEP 2-2: Step of Determining Equivalent Temperature of Coil in Transformer

<Determination of Average Ambient Temperature>

While the temperature of the ambient in which the transformer is installed is not constant, a method can be applied that takes into consideration a temperature variation in a day and that in a year to determine the average ambient temperature in the whole operating period of the transformer (for example, Tadao Minagawa, Eiichi Nagao, Ei Tsuchie, Hiroshi Yonezawa, Daisuke Takayama, and Yutaka Yamanaka “Degradation Characteristics of O-rings on Highly Aged GIS,” IEEJ Transactions on Power and Energy, Volume 125, No. 3, 2005).

<Determination of Average Operating Load Factor>

The average of the operating load factor in the whole operating period of the transformer can be determined from records of a substation in which the transformer is installed.

<Determination of Equivalent Temperature of Coil>

First, based on the relation between the operating load factor of the transformer and the ambient temperature, and the coil temperature in the transformer, which is ascertained in above-described STEP 2-1, the coil temperatures from the bottom part to the upper part in the transformer at the above-described average ambient temperature and average operating load factor are determined.

Next, a relation between the coil temperatures from the bottom part to the upper part in the transformer and the rate of decrease of the DBDS concentration is ascertained. As to the temperature in the transformer, the coil's lower part has the lowest temperature and the coil's upper part has the highest temperature. Reaction between DBDS and copper has temperature dependency. Specifically, the reaction rate is higher as the temperature is higher. Therefore, at the coil's lower part having a relatively lower temperature, the rate of decrease of the DBDS concentration is lower while the rate of decrease of the DBDS concentration is higher at the coil's upper part having a relatively higher temperature.

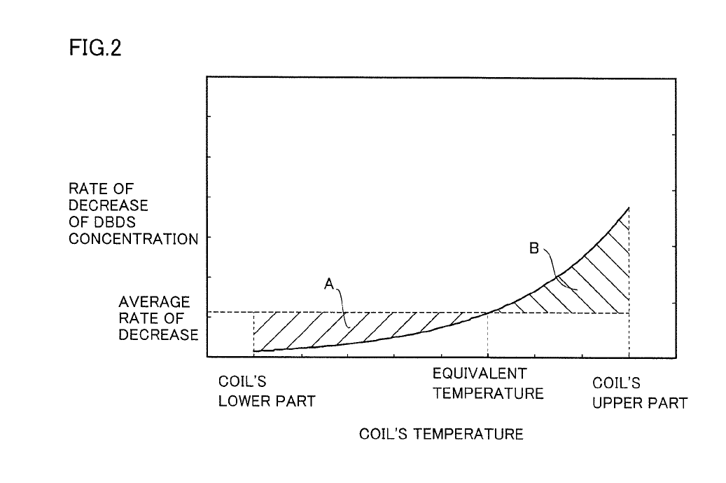

Specifically, the chemical reaction generating copper sulfide has a reaction rate which is doubled when the temperature increases by 10° C. Based on this temperature dependency, it is estimated that the rate of decrease of the DBDS concentration is also doubled as the coil temperature increases by 10° C. Then, based on this estimation, a graph can be made showing a relation between the coil temperatures from the bottom part to the upper part in the transformer and the rate of decrease of the DBDS concentration (a schematic graph is shown in FIG. 2).

In FIG. 2, the temperature where respective values of the areas of regions A and B are equal to each other can be determined as the equivalent temperature of the coil.

STEP 2-3: Step of Determining Average Rate of Decrease of DBDS Concentration

The rate of decrease of the DBDS concentration at this equivalent temperature is the average rate of decrease of the DBDS concentration (see FIG. 2).

STEP 2-4: Step of Determining Estimated Decrease of DBDS Concentration

From the information about operating years of the transformer and the average rate of decrease of the DBDS concentration determined in the above-described STEP 2-3, an estimated decrease of the DBDS concentration relative to the DBDS concentration at the start of operation can be determined.

(3) Step of Calculating Estimated Initial Value of DBDS Concentration

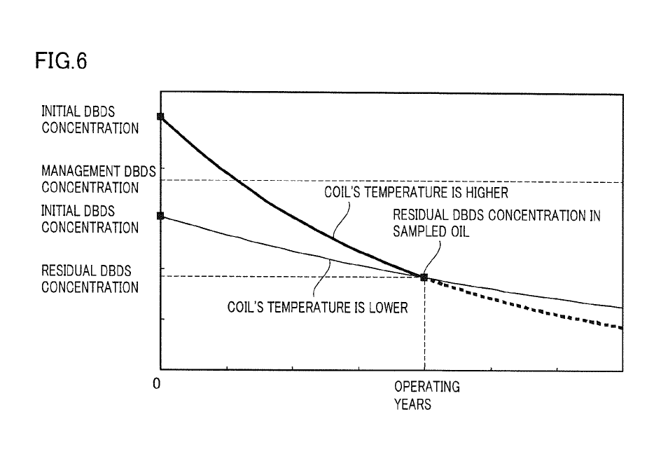

FIG. 6 is a conceptual diagram for illustrating how to calculate the DBDS concentration at the start of operation. From the DBDS concentration in a sampled oil (residual DBDS concentration) and the estimated decrease of the DBDS concentration determined in STEP 2-4 (the value determined from the average rate of decrease of the DBDS concentration and the operating years), the DBDS concentration at the start of operation (initial DBDS concentration) can be determined.

Even when the DBDS concentration in an insulating oil sampled from a transformer in operation (residual DBDS concentration) is the same, the DBDS concentration at the start of operation (initial DBDS concentration) is different if the coil temperature is different. For example, in the case where the coil temperature is higher, the rate of decrease of the DBDS concentration is higher and the decrease of the DBDS concentration relative to the DBDS concentration at the start of operation is larger, and therefore, the DBDS concentration at the start of operation has a larger value.

(4) Step of Comparing Initial Dihenzyl Disulfide Concentration with Specific Management Value

As a management value of the DBDS concentration in the oil (DBDS management concentration), 10 ppm is recommended (for example, CIGRE WG A2-32, “Copper sulphide in transformer insulation,” Final Report Brochure 378, 2009). The DBDS concentration at the start of operation as determined by the above-described method can be compared with the management value to predict that, if the DBDS concentration is higher than the management value, there is a high probability of abnormality occurrence due to copper sulfide deposited on the insulating paper. In the case where it is determined that the probability of abnormality occurrence is higher, there is a probability that a malfunction will occur to the oil-filled electrical device due to copper sulfide, and accordingly a warning may be issued for example.

Thus, the diagnostic method for the copper sulfide in the oil-filled electrical device according to the present invention includes: the step of determining the DBDS concentration by analyzing an insulating oil sampled from an existing (operating) oil-filled electrical device; the step of determining the average rate of decrease of the DBDS concentration, in consideration of the coil temperature of the oil-filled electrical device and the distribution of the coil temperature; and the step of determining a decrease of the DBDS concentration relative to the DBDS concentration at the start of operation, from the operating years of the oil-filled electrical device, to thereby determine the DBDS concentration at the start of operation.

Accordingly, the concentration of DBDS which is a causative substance at the start of operation can be compared with a predetermined management value to evaluate the risk of occurrence of dielectric breakdown due to copper sulfide in an oil-filled electrical device.

In the foregoing description, the detailed explanation is given mainly of the case of the transformer by way of example. The present invention, however, is also applicable to other oil-filled electrical devices, as well as the fields of devices and systems using a sulfur-contained oil such as mineral oil.

It should be construed that embodiments disclosed herein are by way of illustration in all respects, not by way of limitation. It is intended that the scope of the present invention is defined by claims, not by the above description, and encompasses all modifications and variations equivalent in meaning and scope to the claims.

1. A method of predicting probability of abnormality occurrence in an oil-filled electrical device, comprising the steps of:
(1) measuring a residual dibenzyl disulfide concentration in an insulating oil sampled from an oil-filled electrical device in operation;
(2) determining an estimated decrease of said residual dibenzyl disulfide concentration, relative to an initial dibenzyl disulfide concentration at the start of operation of said oil-filled electrical device;
(3) calculating said initial dibenzyl disulfide concentration from said residual dibenzyl disulfide concentration and said estimated decrease; and
(4) comparing said initial dibenzyl disulfide concentration with a specific management value.

2. The method according to claim 1, wherein said estimated decrease is determined from an average rate of decrease of dibenzyl disulfide concentration and operating years of said oil-filled electrical device.

3. The method according to claim 2, wherein said average rate of decrease is determined as a rate of decrease of dibenzyl disulfide concentration at an equivalent temperature of a coil provided in said oil-filled electrical device.

4. The method according to claim 3, wherein said equivalent temperature of the coil is determined from test data of the oil-filled electrical device, an operating load factor, and information about an ambient temperature.
